(19) United States
(12) Patent Application Publication
(10) Pub. No.: US 2013/0181040 A1
(43) Pub. Date: Jul. 18, 2013

(54) SEMICONDUCTOR DEVICE MANUFACTURING SYSTEM AND SEMICONDUCTOR DEVICE MANUFACTURING METHOD

(71) Applicant: Tokyo Electron Limited, Tokyo (JP)

(72) Inventors: Shinjiro Watanabe, Yamanashi (JP); Itaru Iida, Yamanashi (JP); Muneo Harada, Iwate (JP)

(73) Assignee: Tokyo Electron Limited, Tokyo (JP)

(21) Appl. No.: 13/723,771

(22) Filed: Dec. 21, 2012

(30) Foreign Application Priority Data
Jan. 12, 2012 (JP) 2012-004148

(51) Int. Cl. H01L 21/48

(52) U.S. Cl. CPC H01L 21/4814
USPC 228/211; 228/18

(57) ABSTRACT

Provided is a semiconductor device manufacturing system according to the present disclosure which manufactures a semiconductor device using a chip stack. The system includes a chip reducing apparatus and a chip bonding apparatus, the chip reducing apparatus includes a reduction chamber, an oxide film of the surface of the terminal of each chip is reduced in the reduction chamber, the chip bonding apparatus includes a reflow chamber isolated from the reduction chamber, a solder ball is bonded to the terminal of each chip in the reflow chamber, and the chip bonding apparatus is installed separately from the chip reducing apparatus.

### CROSS-REFERENCE TO RELATED APPLICATIONS

This application is based on and claims priority from Japanese Patent Application No. 2012-004148, filed on Jan. 12, 2012, with the Japanese Patent Office, the disclosure of which is incorporated herein in its entirety by reference.

### TECHNICAL FIELD

The present disclosure relates to a semiconductor device manufacturing system and method for manufacturing a semiconductor device with a solder bump bonded to a terminal thereof.

### BACKGROUND

When a semiconductor device is manufactured, a solder bump is bonded to a terminal made of a metal in an IC substrate (chip) made out of a semiconductor wafer. After formed by, for example, a vapor deposition, the terminal is formed with an oxide film on the surface thereof by, for example, being contacted with oxygen in the atmosphere. The oxide film suppresses the bonding of the terminal and the solder bump.

Therefore, in the related art, the oxide film on the surface of the terminal is removed by a flux before the solder bump is bonded to the terminal. Specifically, while activating the surface of the terminal to remove (reduce) the oxide film, the flux covers the surface of the terminal, thereby suppressing a new oxidation and maintaining the activation state of the surface of the terminal. However, the flux may sometimes remain as residue between the surface of the terminal and the solder bump.

Further, when the solder bump is melted and bonded to the terminal, gas generated from the heated flux may sometimes remain within the solder bump as a void.

In order to solve these problems, a method is used where the vapor of carboxylic acid, for example, the vapor of formic acid is supplied to the chip and the chip is heated under the depressurized atmosphere (see, e.g., Japanese Patent No. 3378852). In this method, the formic acid reduces the oxide film on the surface of the terminal of the chip without generating residue. In addition, the formic acid does not generate gas even if heated. Furthermore, because the atmosphere is depressurized, gas is discharged from the solder bump even if the gas is generated. The heated solder bump is melted and bonded to the terminal.

Recently, in order to decrease a footprint of a semiconductor device, a three-dimensional mounting method has been developed where a plurality of chips are stacked to manufacture a semiconductor device. In the three-dimensional mounting method, a wiring made out of a conductor and extending through a chip in the thickness direction of the chip, for example, a through silicon via (TSV) is formed in each of the chips, an electrode pad (terminal) formed at an end of the wiring of one chip is bonded to a solder bump formed at an end of the wiring of another chip, thereby forming a circuit three-dimensionally. The method disclosed in Japanese Patent No. 3378852 is also applied to the bonding of an electrode pad in one chip and the solder bump in another chip in the three-dimensional mounting method.

### SUMMARY

An aspect of the present disclosure provides a semiconductor device manufacturing system for manufacturing a semiconductor device with a solder bump bonded to a terminal, the system including a reducing apparatus including a first processing chamber within which an oxide film on the surface of the terminal is reduced, and a bonding apparatus installed separately from the reducing apparatus and including a second processing chamber isolated from the first processing chamber, the bonding apparatus performing the bonding of the solder bump to the terminal within the second processing chamber.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a horizontal cross-sectional view schematically illustrating a configuration of a semiconductor device manufacturing system according to an exemplary embodiment of the present disclosure.

FIGS. 2A and 2B are cross-sectional views schematically illustrating a configuration of a chip stack in FIG. 1, in which FIG. 2A illustrates the configuration prior to performing a reduction processing and a reflow processing, and FIG. 2B illustrates the configuration after performing the reduction processing and the reflow processing.

FIG. 3 is a cross-sectional view taken along line of FIG. 1, and schematically illustrating a configuration of a chip reducing apparatus in FIG. 1.

FIG. 4 is a cross-sectional view taken along line IV-IV of FIG. 1, and schematically illustrating a configuration of a chip bonding apparatus in FIG. 1.

FIGS. 5A to 5C are flow charts for describing the reduction processing and the reflow processing performed in the semiconductor device manufacturing system in FIG. 1.

FIGS. 6A to 6C are flow charts for describing the reduction processing and the reflow processing performed in the semiconductor device manufacturing system in FIG. 1.

FIGS. 7A to 7C are flow charts for describing the reduction processing and the reflow processing performed in the semiconductor device manufacturing system in FIG. 1.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

In the method disclosed in Japanese Patent No. 3378852, the reduction of the oxide film on the surface of the terminal by the formic acid and the fusion bonding of the solder bump by heating are performed in the same processing chamber. Accordingly, there is a problem in that the melting and bonding of the solder bump cannot be performed while the reduction of the surface of the terminal is being performed and the throughput for manufacturing semiconductor devices is decreased.

An object of the present disclosure is to provide a semiconductor device manufacturing system and method capable of increasing the throughput for manufacturing semiconductor devices.

To accomplish the object as described above, an exemplary embodiment of the present disclosure provides a semiconductor device manufacturing system for manufacturing a semiconductor device with a solder bump bonded to a terminal. The system includes a reducing apparatus including a first processing chamber within which an oxide film on the surface of the terminal is reduced, and a bonding apparatus installed separately from the reducing apparatus and including a second processing chamber isolated from the first processing chamber, the bonding apparatus performing the bonding of the solder bump to the terminal within the second processing chamber.

In the above-described semiconductor device manufacturing system, the reducing apparatus and the bonding apparatus are connected to each other.

In the above-described semiconductor device manufacturing system, the reducing apparatus includes a first nitrogen supplying device configured to supply nitrogen into the first processing chamber, and the bonding apparatus includes a second nitrogen supplying device configured to supply nitrogen into the second processing chamber.

In the above-described semiconductor device manufacturing system, the reducing apparatus includes: a depressurizing device configured to depressurize the inside of the first processing chamber; a placing table disposed within the first processing chamber and configured to load the semiconductor device thereon; and a compression device configured to protrude into the first processing chamber to face the placing table. The compression device includes: a cylindrical portion, of which an inner portion is opened to the atmosphere, the cylindrical portion defining the inner portion within the first processing chamber and being extendible toward the placing table; and a contacting portion installed at the front end of the cylindrical portion in the placing table side and contacted with the semiconductor device loaded on the placing table when the cylindrical portion is extended.

In the above-described semiconductor device manufacturing system, the reducing apparatus includes a carboxylic acid supplying device configured to supply a carboxylic acid into the first processing chamber.

In the above-described semiconductor device manufacturing system, the carboxylic acid is formic acid.

To accomplish the object as described above, another exemplary embodiment of the present disclosure provides a semiconductor device manufacturing method performed in a semiconductor device manufacturing system for manufacturing a semiconductor device with a solder bump bonded to a terminal. The method includes: reducing an oxide film on the surface of the terminal within a first processing chamber; and bonding the solder bump to the terminal in a second processing chamber that is isolated from the first processing chamber. While the oxide film on the surface of a terminal in one semiconductor device is being reduced, a solder bump is bonded to a terminal in another semiconductor device.

In the above-described semiconductor device manufacturing method, nitrogen is filled within the first processing chamber and the second processing chamber while the semiconductor device is being transported from the reducing apparatus to the bonding apparatus.

In the above-described semiconductor device manufacturing method, the inside of the first processing chamber into which the semiconductor device is carried is depressurized in the reducing apparatus, and then a carboxylic acid is supplied into the first processing chamber.

In the above-described semiconductor device manufacturing method, the carboxylic acid is formic acid.

In the above-described semiconductor device manufacturing method, the inside of the second processing chamber is depressurized when the solder bump is melted and bonded to the terminal of the semiconductor device carried into the second processing chamber in the bonding apparatus.

According to the present disclosure, the bonding apparatus that bonds the solder bump to the terminal is installed separately from the reducing apparatus that reduces the oxide film on the surface of the terminal. Therefore, while an oxide film of the terminal surface of one semiconductor device is being reduced in the reducing apparatus, the solder bump and the terminal of another semiconductor device may be bonded in the bonding apparatus. Accordingly, the throughput for manufacturing semiconductor devices will not be decreased.

Hereinafter, exemplary embodiments of the present disclosure will be described with reference to the accompanying drawings.

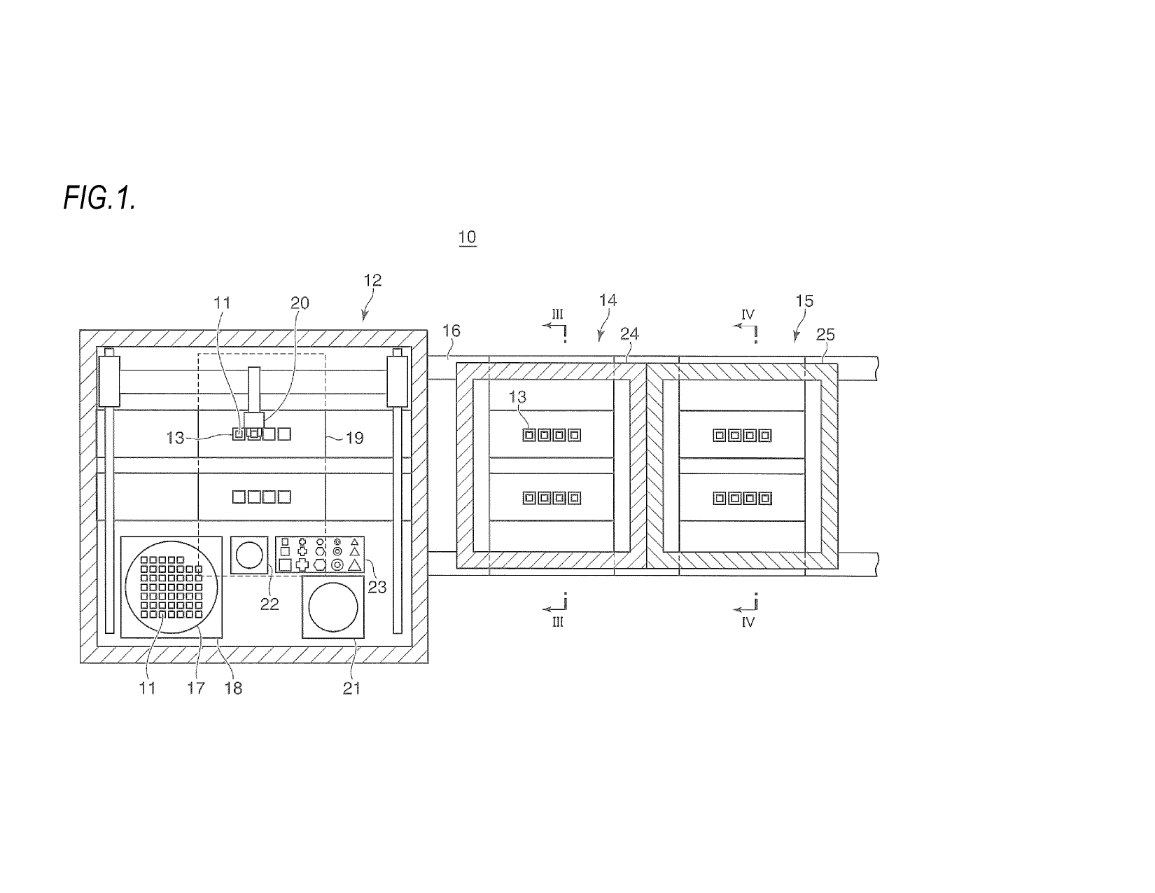

FIG. 1 is a horizontal cross-sectional view schematically illustrating a configuration of a semiconductor device manufacturing system according to an exemplary embodiment. For simple description, FIG. 1 illustrates a horizontal cross-sectional view in a state where the top mechanisms of various apparatuses provided in the semiconductor device manufacturing system are removed.

In FIG. 1, a semiconductor device manufacturing system 10 includes: a chip stacking apparatus 12 that stacks a plurality of IC circuits (chips) 11; a chip reducing apparatus 14 that performs a reduction processing for a set of chips (“chip stack”) 13 in which plural of chips 11 are stacked; a chip bonding apparatus 15 that performs a reflow processing to chip stack 13; and a guide 16 disposed across chip reducing apparatus 14 and chip bonding apparatus 15.

Chip stacking apparatus 12, chip reducing apparatus 14, and chip bonding apparatus 15 are disposed in a single line, and especially, chip reducing apparatus 14 and chip bonding apparatus 15 are disposed to be in contact with each other.

Chip stacking apparatus 12 includes: a chip storage place 18 where a dicing film is loaded on which plurality of chips 11 are disposed in parallel; a transporting tray 19 supported by guide 16; a pickup unit 20 that moves chips 11; a dipping unit 21 filled with solder paste; a camera unit 22 that photographs the bottom surface of a chip 11 selected by pickup unit 20; and a tool exchange unit 23 loaded with various head tools of pickup unit 20 that are exchanged based on the types of chips 11.

In chip stacking apparatus 12, pickup unit 20 selects one chip 11 in chip storage place 18 and moves chip 11 to dipping unit 21, dips the bottom surface of chip 11 in solder paste so that the solder paste is adhered to the bottom surface, and moves chip 11 to camera unit 22 to photograph the bottom surface of chip 11, thereby confirming the state of the solder paste adhered to the bottom surface. Then, chip 11 is moved to transporting tray 19 and is laid on another chip 11 already disposed on transporting tray 19. Accordingly, chip stack 13 is configured on transporting tray 19 on which plural chips 11 are stacked. In the present exemplary embodiment, eight chip stacks 13 are configured on transporting tray 19.

Transporting tray 19 includes a rectangular plate-shaped support tray 19a supported by guide 16, and two chip trays 19b removably loaded on support tray 19a. In the present exemplary embodiment, each of chip trays 19b is provided with chip stacks 13 described above which are arranged by four in a line. Guide 16 carries transporting tray 19 loaded with chip stacks 13 from chip stacking apparatus 12 to chip reducing apparatus 14, and then, from chip reducing apparatus 14 to chip bonding apparatus 15.

Two chip trays 19b in transporting tray 19 carried from chip stacking apparatus 12 to chip reducing apparatus 14 are accommodated in a reduction chamber 24 of chip reducing apparatus 14, and a reduction processing is performed for each chip stack 13 in reduction chamber 24. Two chip trays 19b in transporting tray 19 carried from chip reducing apparatus 14 to chip bonding apparatus 15 are accommodated in a reflow chamber 25 of chip bonding apparatus 15, and a reflow processing is performed for each chip stack 13 in reflow chamber 25. The detailed configurations and operations of chip reducing apparatus 14 and chip bonding apparatus 15 will be described below.

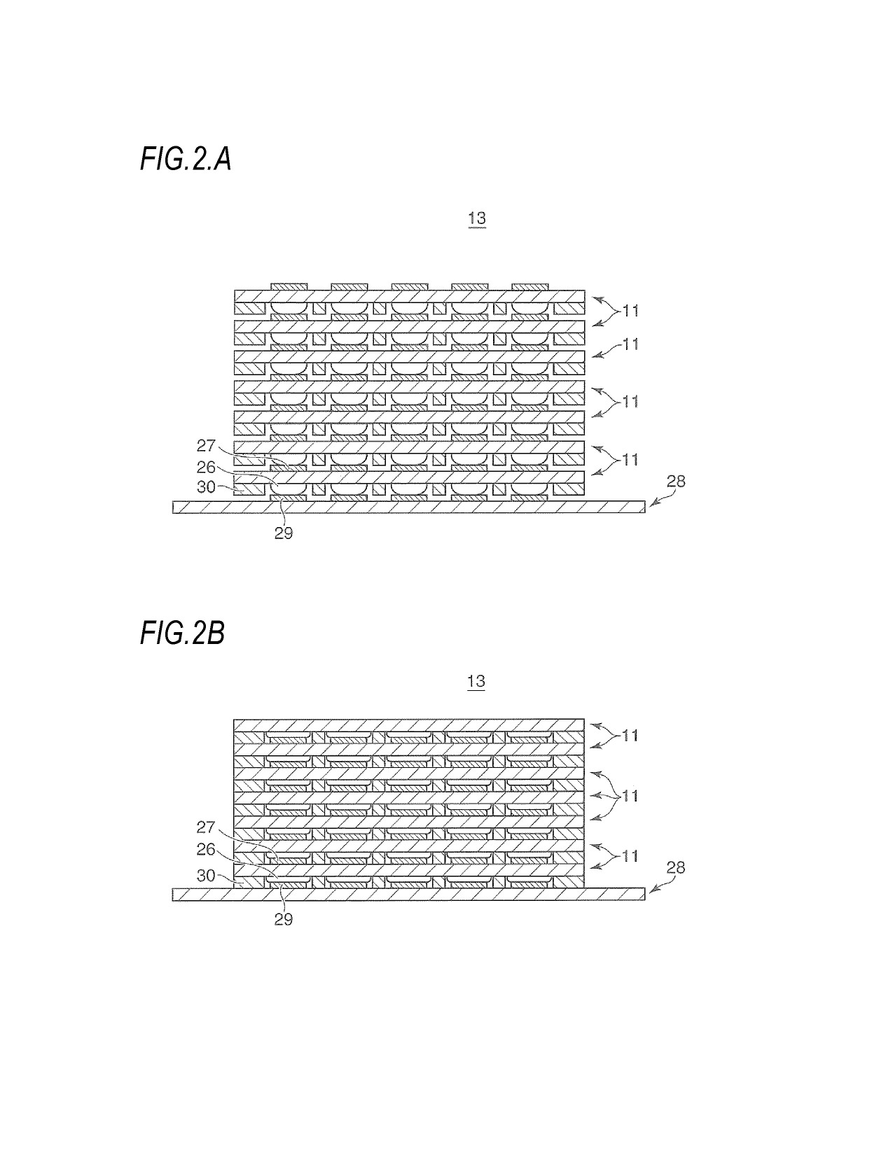

FIGS. 2A and 2B are cross-sectional views schematically illustrating a configuration of a chip stack in FIG. 1, in which FIG. 2A illustrates the configuration prior to performing the reduction processing and the reflow processing, and FIG. 2B illustrates the configuration after performing the reduction processing and the reflow processing.

As illustrated in FIG. 2A, chip stack 13 is configured by stacking plural of chips 11 on a base chip 28 disposed in the lowest. A plurality of electrode pads 29 are formed on the top surface of base chip 28, a plurality of solder bumps 26 are formed and an insulation layer 30 is formed to avoid the solder bumps 26 on the bottom surface of each chip 11, and a plurality of terminals 27 are formed on the top surface of each chip 11. Solder bumps 26 on the bottom surface of chip 11 are formed by the solder paste which is adhered to the bottom surface of chip 11 in dipping unit 21. Each solder bump 26 of the bottom surface in each chip 11 is connected to one of terminals 27 on the top surface via a wiring extending through chip 11 in a thickness direction thereof, for example, a TSV (not illustrated).

A chip stack 13 is configured, in chip stacking apparatus 12, by superposing a chip 11 on base chip 28 in such a manner that each solder bump 26 on the bottom surface of chip 11 is contacted with each terminal 27 on the top surface of base chip 28, superposing another chip 11 on chip 11 superposed directly on base chip 28 in such a manner that each solder bump 26 on the bottom surface of another chip 11 is contacted with each terminal 27 on the top surface of chip 11, and thereafter, repeating the superposition of chips 11. In that event, since the total thickness of terminal 27 and solder bump 26 is larger than the thickness of insulation layer 30, insulation layer 30 of an upper chip 11 is not contacted with the top surface of a lower chip 11 before the reflow processing for chip stack 13 is performed.

Though solder bumps 26 of upper chip 11 are melted and bonded to terminals 27 of lower chip 11 when the reflow processing for chip stack 13 is performed, the shapes of solder bumps 26 collapses. Accordingly, upper chip 11 subsides toward lower chip 11 and insulation layer 30 of upper chip 11 is contacted with the top surface of lower chip 11 (see, e.g., FIG. 2B).

In the present exemplary embodiment, each chip stack 13 configured in chip stacking apparatus 12 is transported together with transporting tray 19 to chip reducing apparatus 14, chip reducing apparatus 14 reduces the oxide film of the surface of each terminal 27 of chip 11 of each chip stack 13 with a carboxylic acid, for example, formic acid (reduction processing), and chip bonding apparatus 15 melts solder bumps 26 of a chip 11 of a reduction processing performed chip stack 13 to be bonded to terminals 27 of which the oxide film is removed from the surface of another chip 11 (reflow processing). Accordingly, a semiconductor device is manufactured from chip stack 13.

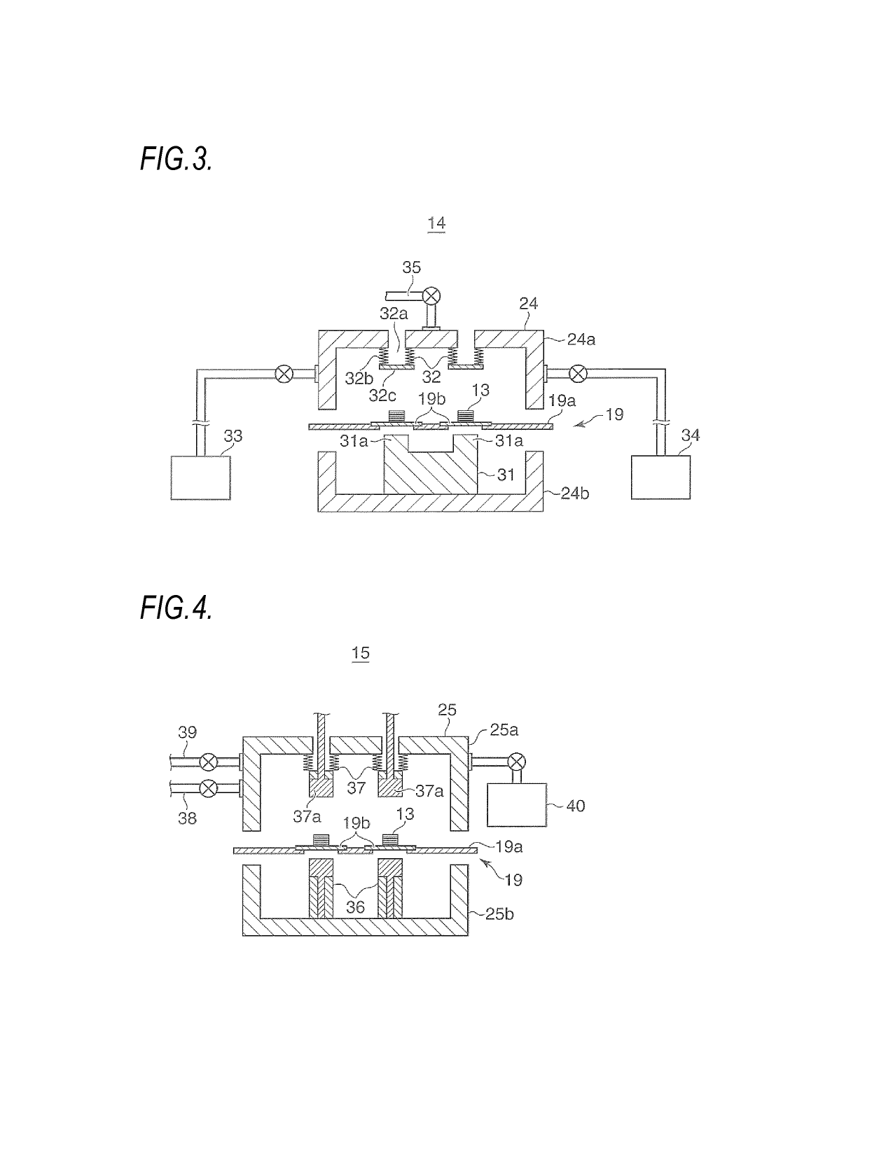

FIG. 3 is a cross-sectional view taken along line of FIG. 1, and schematically illustrating a configuration of the chip reducing apparatus of FIG. 1.

In FIG. 3, chip reducing apparatus 14 includes: a case shaped reduction chamber 24 (a first processing chamber) that accommodates two chip trays 19b in transporting tray 19; a lower stage 31 (a placing table) disposed in the bottom portion within reduction chamber 24; a compression cylinder 32 (a compression device) that protrudes into reduction chamber 24 from a ceiling portion of reduction chamber 24; a reducing agent supplying device 33 (a carboxylic acid supplying device) that supplies vapor of carboxylic acid, for example, the vapor of formic acid as a reducing agent, into reduction chamber 24; a dry pump 34 (a depressurizing device) that depressurizes the inside of reduction chamber 24; a nitrogen gas supplying pipe that supplies nitrogen gas into reduction chamber 24; and a heater (not illustrated) that heats the atmosphere within reduction chamber 24.

Lower stage 31 includes two protrusions 31a which are formed appositionally to correspond to two chip trays 19b in transporting tray 19 transported into reduction chamber 24, respectively. Compression cylinder 32 includes a retractable portion (a cylindrical portion) 32b formed by a retractable cylindrical bellows of which an inner portion 32a is opened to the atmosphere to be communicated with the outside of reduction chamber 24, and which defines inner portion 32a within reduction chamber 24, and a plate shaped contacting portion 32c installed at the front end of retractable portion 32b in lower stage 31 side, and compression cylinder 32 is disposed to face protrusions 31a of lower stage 31. In chip reducing apparatus 14, eight compression cylinders 32 are disposed, of which the number is the same as the number of chip stacks 13 loaded on transporting tray 19.

Reduction chamber 24 may be divided into an upper portion 24a and a lower portion 24b. When reduction chamber 24 is divided into upper portion 24a and lower portion 24b, transporting tray 19 is introduced between upper portion 24a and lower portion 24b by guide 16, and the position of introduced transporting tray 19 is adjusted such that chip tray 19b faces lower stage 31. The length of transporting tray 19 along a direction perpendicular to the transporting direction by guide 16 (“a width direction”) is larger than the length of reduction chamber 24 along the width direction. Therefore, when transporting tray 19 is introduced between upper portion 24a and lower portion 24b, a part of transporting tray 19, specifically, a part of support tray 19a exists between the lateral wall of upper portion 24a and the lateral wall of lower portion 24b. The length of lower stage 31 along the width direction of each protrusion 31a is set to be smaller than the length along the width direction of each chip tray 19b.

Reducing agent supplying device 33 may supply, for example, acetic acid, acrylic acid, propionic acid, butyric acid, caproic acid, oxalic acid, succinic acid, salicylic acid, malonic acid, enanthic acid, caprylic acid, pelargonic acid, lactic acid, and capric acid, as well as formic acid, as the carboxylic acid.

In reduction chamber 24, upper portion 24a and lower portion 24b are coupled to each other with a part of support tray 19a being interposed therebetween after transporting tray 19 is introduced between upper portion 24a and lower portion 24b which are divided. Accordingly, each of chip trays 19b is shielded from the outside of reduction chamber 24.

When the inside of reduction chamber 24 is depressurized and the pressure becomes lower than the atmospheric pressure, compression cylinders 32 are pulled into the inside of reduction chamber 24, and as described below, retractable portions 32b are extended and contacting portions 32c are contacted with chip stack 13 on chip trays 19b loaded on protrusions 31a of lower stage 31.

FIG. 4 is a cross-sectional view taken along line IV-IV of FIG. 1, and schematically illustrating a configuration of the chip bonding apparatus of FIG. 1.

In FIG. 4, chip bonding apparatus 15 includes: a case shaped reflow chamber (a second processing chamber) 25 that accommodates two chip trays 19b in transporting tray 19; a lower stage 36 disposed in the bottom portion within reflow chamber 25; a compression piston 37 that protrudes into reflow chamber 25 from the ceiling portion of reflow chamber 25; an air introducing pipe 38 that introduces air into reflow chamber 25; a nitrogen gas supplying pipe 39 that supplies nitrogen gas into reflow chamber 25; and a dry pump 40 that depressurizes the inside of reflow chamber 25. Because chip bonding apparatus 15 is installed separately from chip reducing apparatus 14, reflow chamber 25 is isolated from reduction chamber 24.

In chip bonding apparatus 15, eight compression pistons 37 are disposed, of which the number is the same as the number of chip stacks 13 loaded on transporting tray 19 and two lower stages 36 are installed to correspond to two chip trays 19b in transporting tray 19. Each compression piston 37 is disposed to face lower stage 36, and is configured to be movable toward a lower stage 36 by, for example, a motor (not illustrated). A compression portion 37a provided at the front end of each compression piston 37 in lower stage 36 side and each lower stage 36 are with a heating and cooling mechanism, for example, a Peltier element (not illustrated), which is embedded therein.

Reflow chamber 25 may be divided into an upper portion 25a and a lower portion 25b as in reduction chamber 24. When reflow chamber 25 is divided into upper portion 25a and lower portion 25b, transporting tray 19 is introduced between upper portion 25a and lower portion 25b by guide 16, and the position of introduced transporting tray 19 is adjusted such that chip trays 19b face lower stages 36, respectively. The length of transporting tray 19 along the width direction is larger than the length of reflow chamber 25 along the width direction. Therefore, when transporting tray 19 is introduced between upper portion 25a and lower portion 25b, a part of transporting tray 19, specifically, a part of support tray 19a exists between the lateral wall of upper portion 25a and the lateral wall of lower portion 25b. The length of each of lower stages 36 along the width direction is set to be smaller than the length of each of chip trays 19b along the width direction.

In reflow chamber 25, upper portion 25a and lower portion 25b are coupled to each other with a part of support tray 19a being interposed therebetween after transporting tray 19 is introduced between upper portion 25a and lower portion 25b which are divided. Accordingly, each of chip trays 19b is shielded from the outside of reflow chamber 25. In that event, as described below, each of lower stages 36 is loaded with chip tray 19b, and compression portion 37a of each compression piston 37 compresses each chip stack 13 loaded on chip tray 19b.

Next, the reduction processing and the reflow processing performed in semiconductor device manufacturing system 10 will be described.

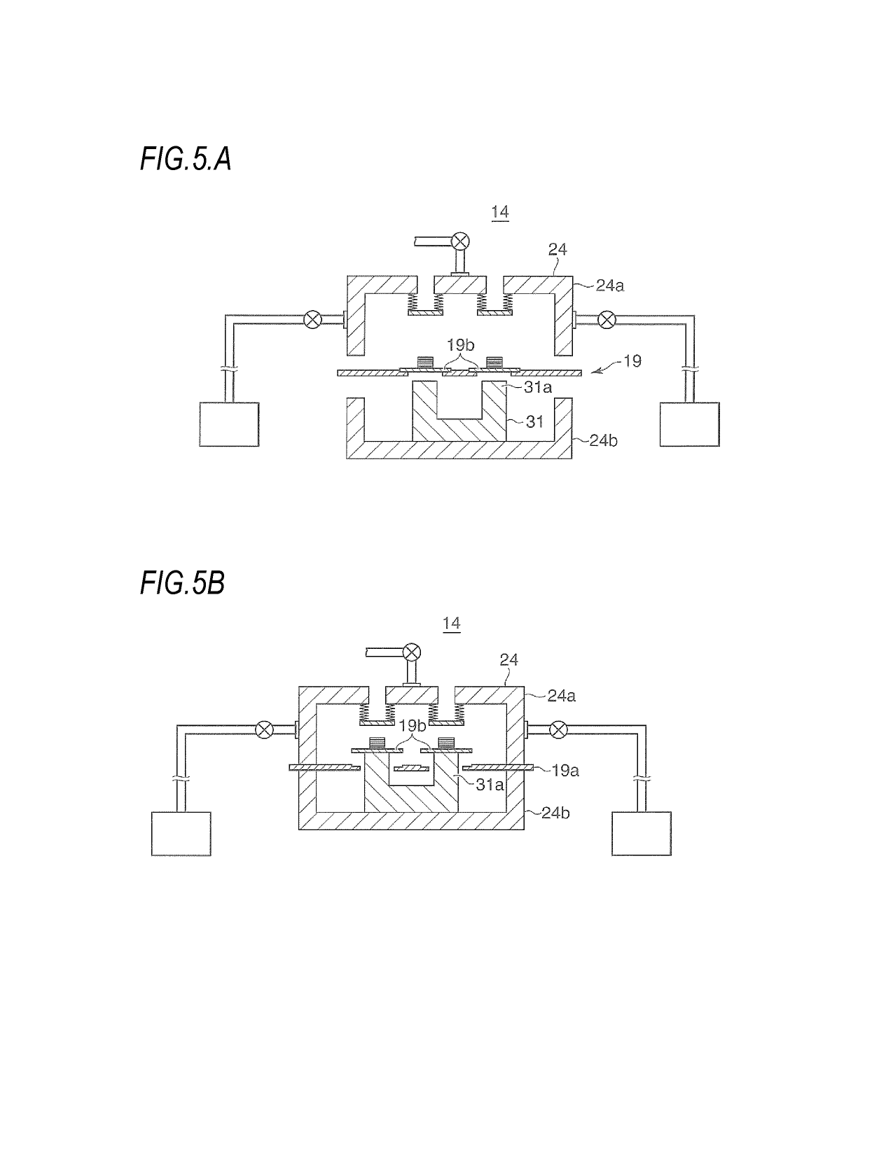

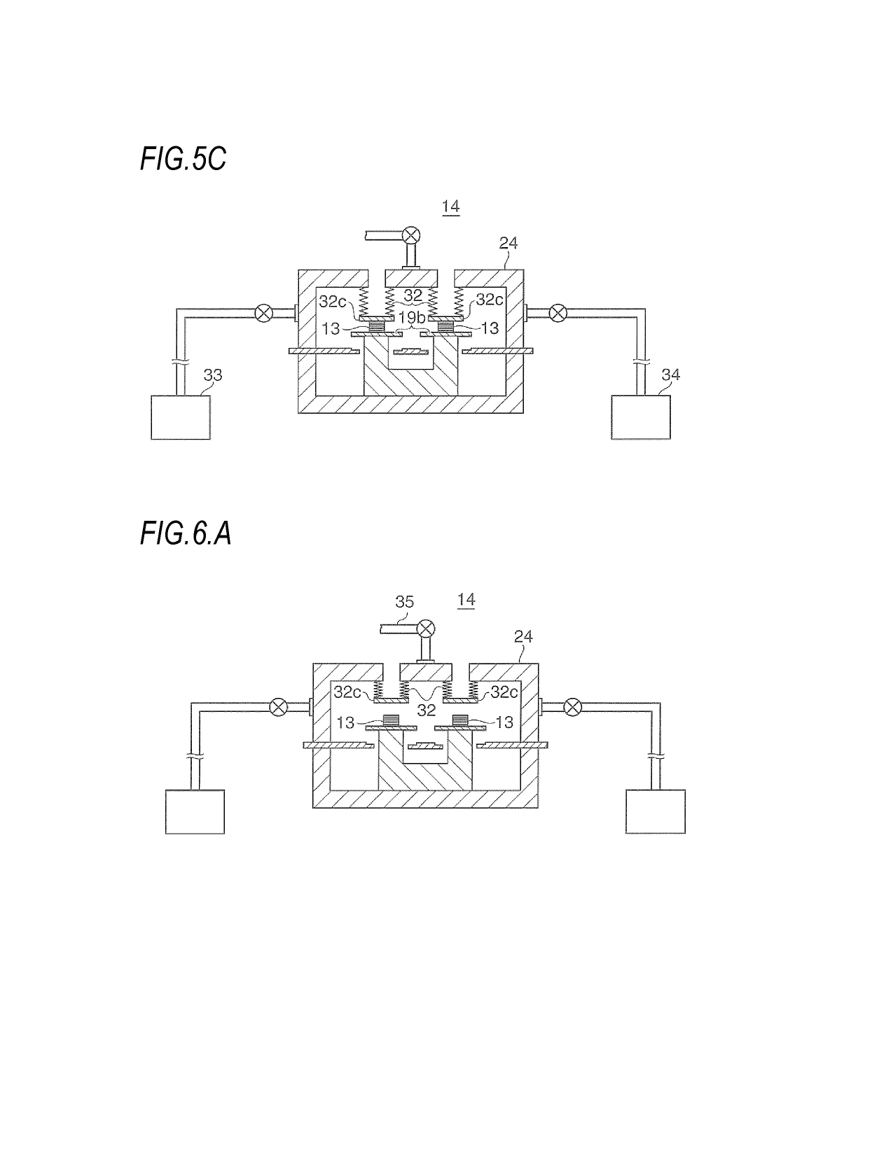

FIGS. 5A to 7C are flow charts for describing the reduction processing and the reflow processing performed in the semiconductor device manufacturing system of FIG. 1.

At first, as illustrated in FIG. 5A, reduction chamber 24 in chip reducing apparatus 14 is divided into upper portion 24a and lower portion 24b. Transporting tray 19 is carried in between upper portion 24a and lower portion 24b, and the position of transporting tray 19 is adjusted such that chip trays 19b face protrusions 31a of lower stage 31, respectively.

Next, as illustrated in FIG. 5B, upper portion 24a and lower portion 24b are coupled to each other and each of chip trays 19b is shielded from the outside of reduction chamber 24. However, in that event, because each protrusion 31a ascends together with lower portion 24b to lift chip tray 19b, chip tray 19b is spaced from support tray 19a.

Next, dry pump 34 depressurizes the inside of reduction chamber 24. In that event, the pressure of the inside of reduction chamber 24 is lower than atmospheric pressure. Therefore, compression cylinders 32 enter into reduction chamber 24 and contacting portions 32c are contacted with chip stacks 13 on chip tray 19b (see, e.g., FIG. 5C).

Thereafter, reducing agent supplying device 33 supplies the vapor of formic acid into reduction chamber 24. Accordingly, the oxide film of the surface of each terminal 27 of chips 11 in each of chip stack 13 is reduced, and the oxide film is removed. After a predetermined length of time elapses, dry pump 34 depressurizes the inside of reduction chamber 24 to discharge the vapor of formic acid that exists within reduction chamber 24. During the removing of the oxide film and the discharge of the vapor of formic acid, each chip stack 13 is pressed by contacting portion 32c of each of compression cylinders 32. Therefore, each chip 11 is not damaged and the position of each chip 11 is not deviated in each of chip stacks 13.

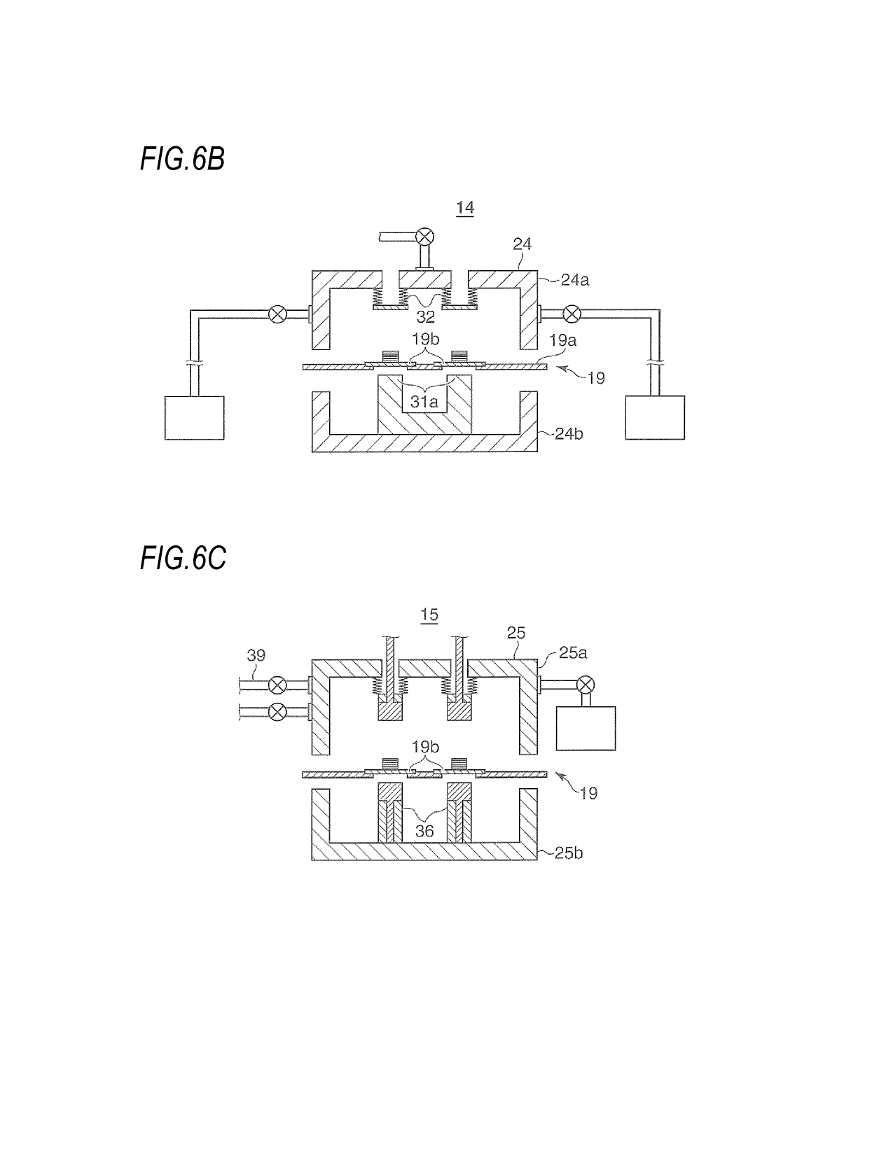

Next, nitrogen gas supplying pipe 35 supplies nitrogen gas into reduction chamber 24, and the inside of reduction chamber 24 is filled with the nitrogen gas. In that event, the pressure of the inside of reduction chamber 24 is equal to or higher than the atmospheric pressure. Therefore, compression cylinders 32 are moved to be returned in reduction chamber 24 and contacting portions 32c are spaced from chip stacks 13 (see, e.g., FIG. 6A). The nitrogen gas is filled within reduction chamber 24 and the vapor of formic acid does not remain within reduction chamber 24. Therefore, when reduction chamber 24 is divided into upper portion 24a and lower portion 24b again, the vapor of formic acid is not discharged to the atmospheric air.

Next, reduction chamber 24 is divided into upper portion 24a and lower portion 24b. In that event, because protrusions 31a descend together with lower portions 24b, chip trays 19b also descends to support tray 19a and is loaded on support tray 19a, again.

Next, transporting tray 19 loaded with chip stacks 13 subjected to the reduction processing illustrated in FIGS. 5A to 6B, is transported from between upper portion 24a and lower portion 24b by guide 16 and introduced into reflow chamber 25 in chip bonding apparatus 15. Specifically, as illustrated in FIG. 6C, reflow chamber 25 in chip bonding apparatus 15 is divided into upper portion 25a and lower portion 25b, transporting tray 19 is introduced between upper portion 25a and lower portion 25b, and the position of transporting tray 19 is adjusted such that each of chip trays 19b faces each of lower stages 36. Prior to introducing transporting tray 19, nitrogen gas supplying pipe 39 supplies the nitrogen gas into reflow chamber 25 and the inside of reflow chamber 25 is filled with the nitrogen gas. Therefore, transporting tray 19 moves within reduction chamber 24 and reflow chamber 25 which are filled with the nitrogen gas.

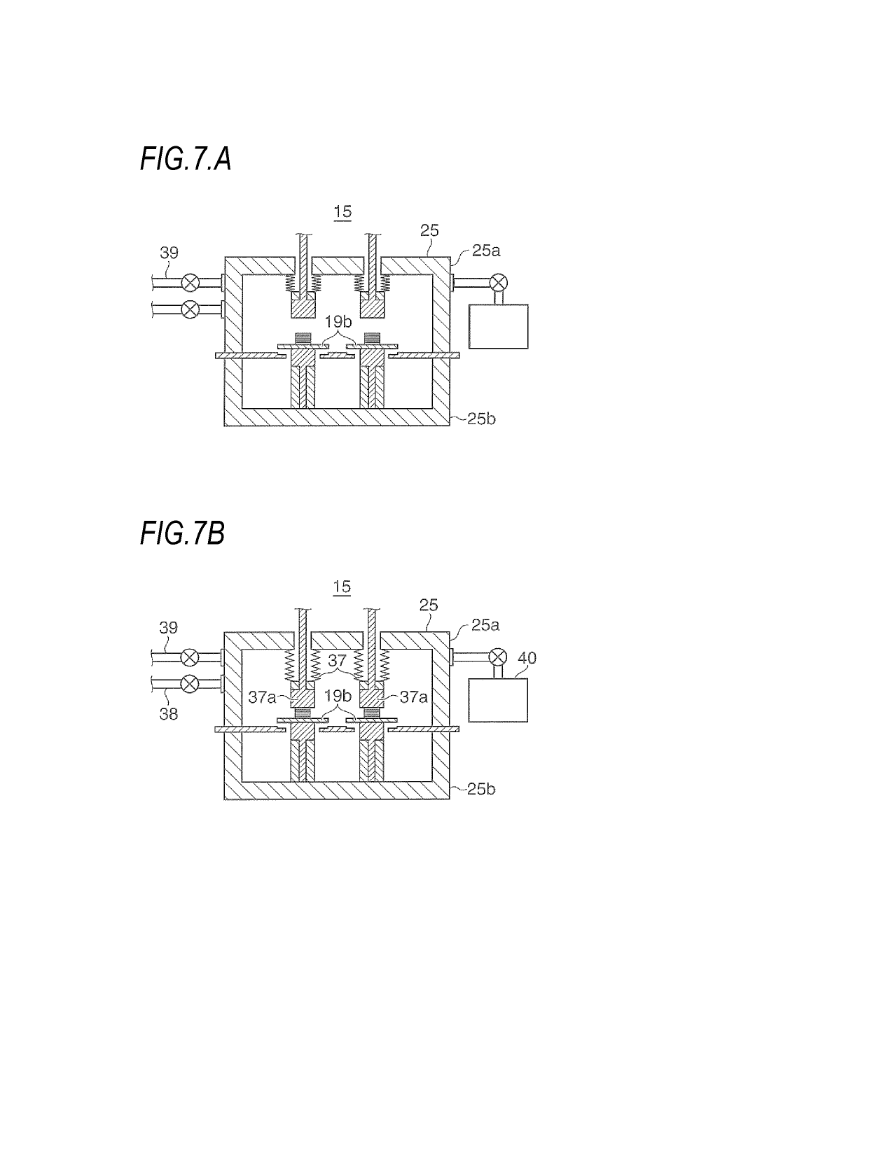

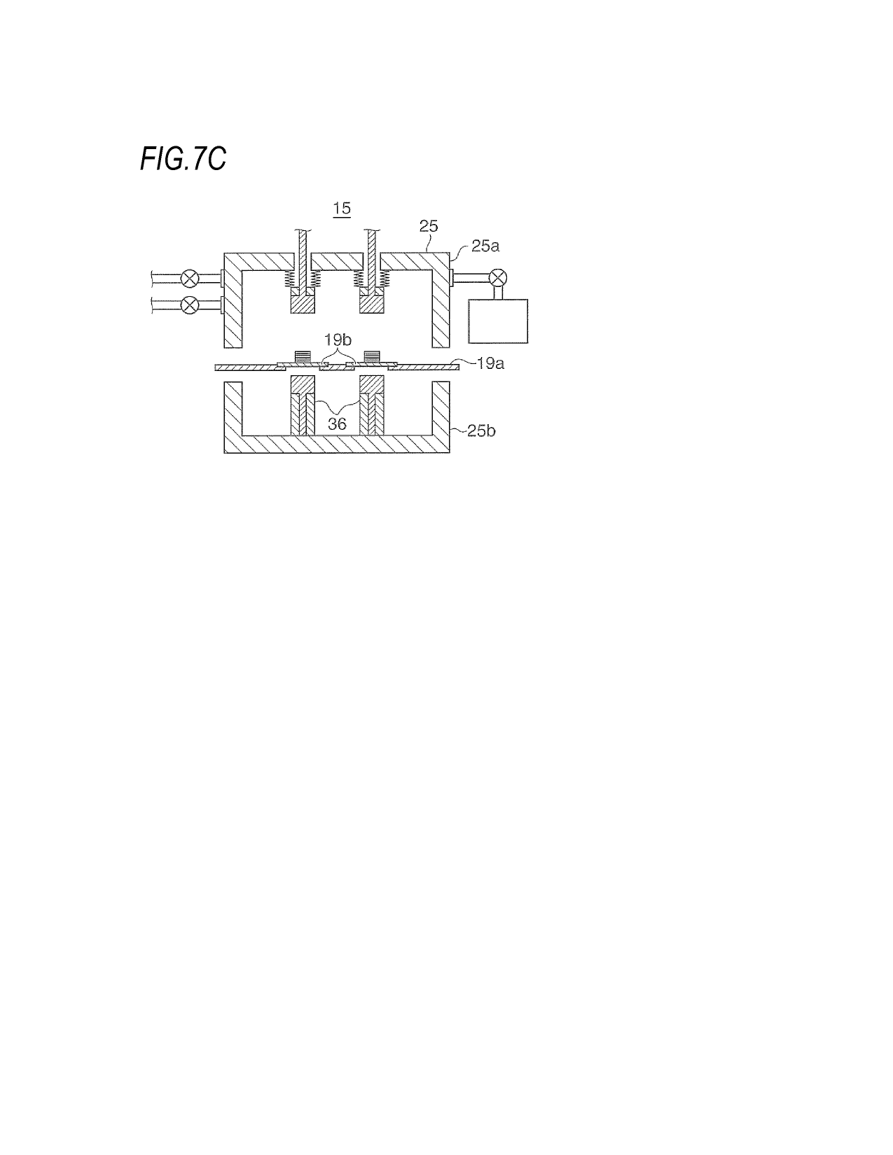

Next, as illustrated in FIG. 7A, upper portion 25a and lower portion 25b are coupled to each other and each of chip trays 19b is shielded from the outside of reflow chamber 25. However, in that event, because each of lower stages 36 ascends together with lower portions 25b to lift chip trays 19b, chip trays 19b are spaced from support tray 19a.

Next, each of compression pistons 37 descends toward chip tray 19b loaded in lower stage 36, and each of compression portions 37a presses each of chip stacks 13 on each chip tray 19b by a load of predetermined value. In that event, heaters of compression portion 37a and each of lower stages 36 heat each of chip stacks 13, and melt solder bumps 26 of a chip 11 by heat to be bonded to terminals 27 of another chip 11.

Next, after the heaters of compression portion 37a and each of lower stages 36 heat each of chip stacks 13 for a predetermined time period, cooling mechanisms of compression portion 37a and each of lower stages 36 cool each of chip stacks 13 rapidly to cure the molten solder bumps 26 (see, e.g., FIG. 7B).

During the processes from FIG. 6C (carrying-in of transporting tray 19) to FIG. 7B (cooling of chip stacks 13), the inside of reflow chamber 25 is filled with nitrogen gas and the pressure thereof is maintained at the atmospheric pressure. That is, because a pressure difference does not exist between the inside of reflow chamber 25 and the outside of reflow chamber 25, the change of the load of predetermined value to be applied to chip stacks 13 by compression portions 37a of compression pistons 37 by the pressure difference does not occur. Accordingly, the bonding of solder bumps 26 and terminals 27 may be performed stably, thereby manufacturing semiconductor devices with stable quality.

Next, dry pump 40 depressurizes the inside of reflow chamber 25, thereby removing the nitrogen gas within reflow chamber 25. Then, air introducing pipe 38 introduces air into reflow chamber 25 (see, e.g., FIG. 7B). Therefore, when reflow chamber 25 is divided into upper portion 25a and lower portion 25b to move transporting tray 19 to the outside, the nitrogen gas is not discharged to the atmosphere.

Next, reflow chamber 25 is divided into upper portion 25a and lower portion 25b. In that event, because lower stage 36 descends together with lower portion 25b, chip tray 19b descends to support tray 19a and is loaded on support tray 19a, again.

Then, transporting tray 19 is moved out from between upper portion 25a and lower portion 25b by guide 16, and the reduction processing and the reflow processing are completed.

According to semiconductor device manufacturing system 10 of the exemplary embodiment of the present disclosure, chip bonding apparatus 15 is installed separately from chip reducing apparatus 14. Therefore, while the oxide film of the surface of terminals 27 of a chip stack 13 is being reduced in chip reducing apparatus 14, solder bumps 26 and terminals 27 of another chip stack 13 may be bonded in chip bonding apparatus 15. That is, the reduction processing illustrated in FIGS. 5A to 6B and the reflow processing illustrated in FIGS. 6C to 7C may be performed concurrently. As a result, the throughput according to the manufacture of semiconductor devices will not be decreased. Reflow chamber 25 in chip bonding apparatus 15 is separated from reduction chamber 24 in chip reducing apparatus 14. Therefore, it is not necessary to execute anti-corrosion measures for various devices of reflow chamber 25. Accordingly, it is not necessary to execute excessive anti-corrosion measures.

In the above-described semiconductor device manufacturing system 10, because chip reducing apparatus 14 and chip bonding apparatus 15 are connected to each other, chip stacks 13 in which the oxide film of the surfaces of terminals 27 are removed in chip reducing apparatus 14 may be transported to chip bonding apparatus 15, thereby reducing the length of time in which the surfaces of terminals 27 are contacted with the atmosphere. More specifically, when transporting tray 19 is transported from chip reducing apparatus 14 to chip bonding apparatus 15, the insides of reduction chamber 24 and reflow chamber 25 are filled with the nitrogen gas, thereby suppressing the surfaces of terminals 27 from being contacted with the atmosphere. Therefore, a natural oxide film will not be formed again in the oxide film removed surfaces of terminals 27.

In the above-described semiconductor device manufacturing system 10, since the vapor of formic acid is supplied to reduction chamber 24 after reduction chamber 24 in the reduction processing is depressurized, the relative concentration of the formic acid may be increased. Therefore, the oxide film of the surfaces of terminals 27 may be removed quickly, and gas may be removed between solder bumps 26 and terminals 27 which are in contact with each other in chip stacks 13. As a result, a void will not be generated between solder bumps 26 and terminals 27.

In the above-described semiconductor device manufacturing system 10, in the reflow processing, when solder bumps 26 of a chip stack 13 are melted and bonded to terminals 27, respectively, the inside of reflow chamber 25 is depressurized. Therefore, since the gas generated from solder bumps 26 is removed, a void will not remain in solder bumps 26.

Although the present disclosure has been described above by using the exemplary embodiments, the present disclosure is not limited to the exemplary embodiments.

Even though the above-described chip reducing apparatus 14 has compression cylinders 32, the compression is not necessary for chip stacks 13 in the reduction reaction. Therefore, if it is possible to loosely supply nitrogen gas and formic acid vapor to such an extent that chips 11 do not scatter from chip stacks 13, it is not necessarily required for chip reducing apparatus 14 to have compression cylinder 32.

In the above-described semiconductor device manufacturing system 10, the reduction processing and the reflow processing are performed. Even when a solder bump is bonded to a terminal in a single chip without stacking chips, the reduction processing and the reflow processing illustrated in FIGS. 5A to 7C using semiconductor device manufacturing system 10 may be performed. Even though transporting tray 19 is transported by guide 16, the transporting unit for transporting tray 19 is not limited thereto. For example, a belt conveyor may be used.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A semiconductor device manufacturing system for manufacturing a semiconductor device with a solder bump bonded to a terminal, the system comprising:
a reducing apparatus including a first processing chamber within which an oxide film on the surface of the terminal is reduced; and
a bonding apparatus installed separately from the reducing apparatus and including a second processing chamber isolated from the first processing chamber, the bonding apparatus performing the bonding of the solder bump to the terminal within the second processing chamber.

2. The semiconductor device manufacturing system of claim 1, wherein the reducing apparatus and the bonding apparatus are connected to each other.

3. The semiconductor device manufacturing system of claim 1, wherein the reducing apparatus includes a first nitrogen supplying device configured to supply nitrogen into the first processing chamber, and the bonding apparatus includes a second nitrogen supplying device configured to supply nitrogen into the second processing chamber.

4. The semiconductor device manufacturing system of claim 1, wherein the reducing apparatus includes: a depressurizing device configured to depressurize the inside of the first processing chamber; a placing table disposed within the first processing chamber, the semiconductor device being loaded on the placing table; and a compression device configured to protrude into the first processing chamber to face the placing table, and
the compression device includes: a cylindrical portion, of which an inner portion is opened to the atmosphere, the cylindrical portion defining the inner portion within the first processing chamber and being extendible toward the placing table; and a contacting portion installed at the front end of the cylindrical portion in the placing table side and configured to be contacted with the semiconductor device loaded on the placing table when the cylindrical portion is extended.

5. The semiconductor device manufacturing system of claim 1, wherein the reducing apparatus includes a carboxylic acid supplying device configured to supply a carboxylic acid into the first processing chamber.

6. The semiconductor device manufacturing system of claim 5, wherein the carboxylic acid is formic acid.

7. A semiconductor device manufacturing method performed in a semiconductor device manufacturing system for manufacturing a semiconductor device with a solder bump bonded to a terminal, the method comprising:
reducing an oxide film on the surface of the terminal within a first processing chamber; and
bonding the solder bump to the terminal in a second processing chamber that is isolated from the first processing chamber,
wherein, while the oxide film on the surface of a terminal in one semiconductor device is being reduced, a solder bump is bonded to a terminal in another semiconductor device.

8. The semiconductor device manufacturing method of claim 7, wherein the nitrogen is filled within the first processing chamber and the second processing chamber while the semiconductor device is being transported from the reducing apparatus to the bonding apparatus.

9. The semiconductor device manufacturing method of claim 7, wherein the inside of the first processing chamber into which the semiconductor device is carried is depressurized in the reducing apparatus, and then a carboxylic acid is supplied into the first processing chamber after depressurizing.

10. The semiconductor device manufacturing method of claim 9, wherein the carboxylic acid is formic acid.

11. The semiconductor device manufacturing method of claim 7, wherein the inside of the second processing chamber is depressurized when the solder bump is melted and bonded to the terminal of the semiconductor device carried into the second processing chamber in the bonding apparatus.
